(19) United States
(12) Patent Application Publication
(10) Pub. No.: US 2019/0363138 A1
(43) Pub. Date: Nov. 28, 2019

(54) ORGANIC EL DISPLAY DEVICE

(71) Applicant: Sharp Kabushiki Kaisha, Sakai City, Osaka (JP)

(72) Inventors: Tomoaki JO, Sakai City (JP); Shinichi KAWATO, Sakai City (JP); Manabu NIBOSHI, Sakai City (JP); Yuto TSUKAMOTO, Sakai City (JP); Hiroshi IMADA, Sakai City (JP); Tokiyoshi UMEDA, Sakai City (JP); Bai ZHANG, Sakai City (JP)

(21) Appl. No.: 16/066,695

(22) PCT Filed: Mar. 29, 2017
(86) PCT No.: PCT/JP2017/012805

§ 371 Date: Jun. 28, 2018

(51) Int. Cl. H01L 27/32; H01L 51/50

(52) U.S. Cl. CPC H01L 27/3211; H01L 2251/552; H01L 51/5004; H01L 51/5064

(57) ABSTRACT

An individual hole transport layer is individually disposed between a common hole transport layer and a light emitting layer in each sub pixel, and the energy level value of the lowest unoccupied molecular orbital of the individual hole transport layer is smaller than the energy level value of the lowest unoccupied molecular orbital of the common hole transport layer, but larger than the energy level value of the lowest unoccupied molecular orbital of the light emitting layer in sub pixel. Thus, a hole can be efficiently injected into the light emitting layer.

### TECHNICAL FIELD

The disclosure relates to an organic EL display device.

### BACKGROUND ART

PTL 1 describes a configuration including: a light emitting layer individually disposed in each sub pixel; a hole injecting layer common to the sub pixels; and an intermediate layer common to the sub pixels disposed between the light emitting layer and the hole injecting layer. According to PTL 1, this intermediate layer facilitates the adjustment of a variety of band gaps, along with a value of a Lowest Unoccupied Molecular Orbital (LUMO) and a Highest Occupied Molecular Orbital (HOMO).

### CITATION LIST

### Patent Literature

PTL 1: JP 2005-183404 A

### SUMMARY

### Technical Problem

In a light emitting layer arranged in each sub pixel, at least one of the energy level value of the Lowest Unoccupied Molecular Orbital (LUMO) and the Highest Occupied Molecular Orbital (HOMO) is different for each light emission color.

Therefore, the mere provision of an intermediate layer common to the sub pixels, as described in PTL 1, may fail to inject a hole efficiently for each light emitting layer in sub pixels. Failure of efficient injection of a hole into the light emitting layer degrades the light emission efficiency of the light emitting layer.

In view of the typical problem described above, the disclosure is to provide an organic EL display device, wherein a hole can be efficiently injected from a hole injecting layer into a light emitting layer.

### Solution to Problem

In order to solve the problem, in an organic EL display device according to one aspect of the disclosure, pixels including a plurality of sub pixels emitting light of different colors are arranged on a display region in a matrix, the organic EL display device including: a light emitting layer individually disposed in each sub pixel and emitting light of a different color for each sub pixel; a positive electrode and a negative electrode arranged facing each other, the light emitting layer being disposed between the positive electrode and the negative electrode; and a common hole transport layer common to the sub pixel, the common hole transport layer being disposed between the positive electrode and the light emitting layer, wherein an individual hole transport layer is further individually disposed in each sub pixel, between the common hole transport layer and the light emitting layer for each sub pixel, and an energy level value of a lowest unoccupied molecular orbital of the individual hole transport layer is smaller than an energy level value of a lowest unoccupied molecular orbital of the common hole transport layer, and greater than an energy level value of a lowest unoccupied molecular orbital of the light emitting layer in the sub pixels.

### Advantageous Effects of the Disclosure

According to one aspect of the disclosure, the effect of obtaining an organic EL display device can be exerted, wherein a hole can be efficiently injected from a hole injecting layer into a light emitting layer.

### BRIEF DESCRIPTION OF THE DRAWINGS

FIG. 1 is a cross-sectional view illustrating the configuration of an organic EL display device according to Embodiment 1 of the disclosure.

FIG. 2 is a plan view illustrating the configuration of the organic EL display device according to Embodiment 1 of the disclosure.

FIG. 3 is a view illustrating a HOMO-LUMO energy gap in a sub pixel of the organic EL display device according to Embodiment 1 of the disclosure.

FIG. 4 is a cross sectional view illustrating the configuration of an organic EL display device according to Embodiment 2 of the disclosure.

FIG. 5 is a view illustrating a HOMO-LUMO energy gap in a sub pixel of the organic EL display device according to Embodiment 2 of the disclosure.

FIG. 6 is a view describing HOMO-LUMO energy gaps in a light emitting layer of the organic EL display device according to Embodiment 1 of the disclosure.

FIG. 7 is a view describing HOMO-LUMO energy gaps of HTL, HTL′, and EML of the organic EL display device according to Embodiment 1 of the disclosure.

FIG. 8 is a cross-sectional view illustrating the configuration of an organic EL display device according to Embodiment 3 of the disclosure.

### DESCRIPTION OF EMBODIMENTS

### Embodiment 1

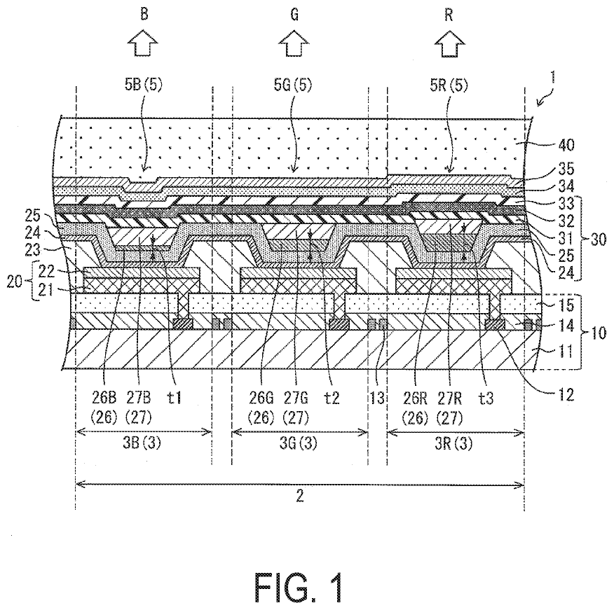

Embodiment 1 of the disclosure will be described with reference to FIGS. 1 to 3, 6, and 7.

### Schematic Configuration of Organic EL Display Device 1

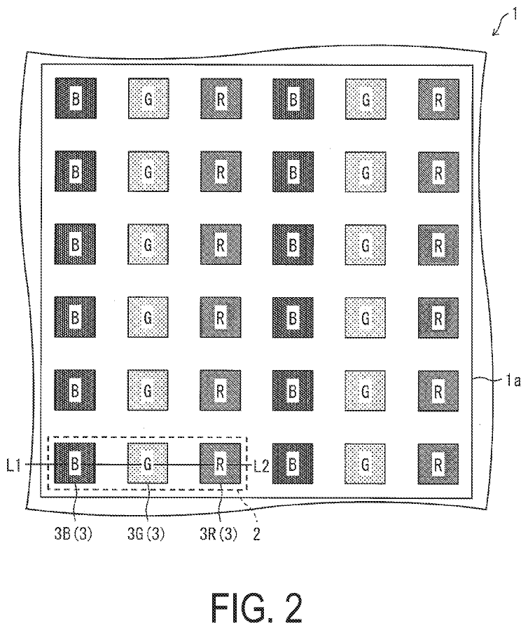

FIG. 2 is a plan view illustrating the configuration of organic EL display device 1 according to Embodiment 1 of the disclosure. FIG. 1 is a cross-sectional view along line L1-L2 illustrated in FIG. 2.

As illustrated in FIG. 2, the organic EL display device 1 includes a plurality of the pixels 2 arranged on the display region 1a in a matrix. Note that in FIG. 2, for convenience of illustration, the number of the pixels 2 is reduced.

As illustrated in FIGS. 1 and 2, each pixel 2 (that is, one pixel) has sub pixels 3 emitting light of different colors. In the present embodiment, each pixel 2 has a red sub pixel 3R emitting red light, a green sub pixel 3G emitting green light, and a blue sub pixel 3B emitting blue light, as sub pixels 3. As a result, the organic EL display device 1 can display a full color image on the display region 1a. Note that as illustrated in FIG. 2, the organic EL display device 1 according to the present embodiment has a pixel array, in which a red sub pixel 3R, a green sub pixel 3G, and a blue sub pixel 3B are each linearly arranged (in stripes). The arrangement is referred to as an RGB stripe array.

As illustrated in FIG. 1, each sub pixel 3 includes a light emitting layer 27 that emits light of a different color for each sub pixel 3, as well as a positive electrode 20 and a negative electrode 34 disposed facing each other and the light emitting layer 27 is disposed between the positive electrode 20 and the negative electrode 34 in each sub pixel 3.

Further, a common hole transport layer 25 common to the sub pixels 3 is disposed between the positive electrode 20 and the light emitting layer 27. In addition, an individual hole transport layer 26 individually disposed in each sub pixel 3 is disposed between the common hole transport layer 25 and the light emitting layer 27 in each sub pixel 3.

A blue organic EL element 5B serving as an organic EL element 5 with a blue light emission color is disposed in the blue sub pixel 3B, a green organic EL element 5G serving as an organic EL element 5 with a green light emission color is disposed in the green sub pixel 3G, and a red organic EL element 5R serving as an organic EL element 5 with a red light emission color is disposed in the red sub pixel 3R. The organic EL element 5 includes the positive electrode 20, the negative electrode 34, and the organic EL layer 30 including a layer between the positive electrode 20 and the negative electrode 34.

The organic EL display device 1 includes a configuration, in which the positive electrode 20, an edge cover 23, the organic EL layer 30, the negative electrode 34, a circularly polarized light filter 35, and a sealing layer 40 are formed on a Thin Film Transistor (TFT) substrate 10. The organic EL display device 1 includes a drive circuit (not illustrated) configured to drive each sub pixel 3. The organic EL display device 1 may further have a touch panel on the sealing layer 40.

The organic EL element 5 of each of the plurality of colors described above is provided on TFT substrate 10.

The plurality of organic EL elements 5, each of which emits each of these colors, are enclosed between the TFT substrate 10 and the sealing layer 40. The organic EL display device 1 according to the present embodiment is a top emitting display device that emits light from the sealing layer 40 side. Details are described below.

### Configuration of TFT Substrate 10

The TFT substrate 10 is a circuit substrate in which a TFT circuit including the TFT 12 and a wiring line 13 is formed. The TFT substrate 10 includes a configuration, in which the support body 11, the TFT 12 and the wiring line 13, a passivation film 14, and an interlayer insulating film 15 are layered in this order.

The support body 11 includes a transparent insulating material such as a plastic film or glass substrate.

The TFT 12 is a driving transistor for supplying a driving current to the organic EL layer 30. The TFT 12 is formed in each sub pixel 3 on the support body 11 or another layer on the support body. While not illustrated, the TFT 12 has a semiconductor layer, a gate electrode, a drain electrode, and a source electrode.

The wiring line 13 is formed on the support body 11, the wiring line 13 including a gate wiring line connected to the gate electrode of the TFT 12, as well as a source wiring line connected to the source electrode of the TFT 12. When viewed from the direction vertical to the substrate surface of the TFT substrate 10, the gate wiring line and the source wiring line are orthogonally crossed. The region surrounded by the gate wiring line and the source wiring line is the sub pixel 3.

The light emission intensity of each sub pixel 3 is determined by scanning and selection by the wiring line 13 and the TFT 12. As described above, the organic EL display device 1 selectively emits each organic EL element 5 at the desired luminance using the TFT 12, thereby displaying images.

The passivation film 14 prevents peeling of the metal film in the TFT 12, thereby protecting the TFT 12. The passivation film 14 is formed on the support body 11 or another layer on the support body 11, to cover the TFT 12. The passivation film 14 is an inorganic insulating film including silicon nitride, silicon oxide, and the like.

The interlayer insulating film 15 provides a leveled surface over irregularities on the passivation film 14. The interlayer insulating film 15 is formed on the passivation film 14. The interlayer insulating film 15 is an organic insulating film including photosensitive resin such as acryl or polyimide.

### Configuration of Organic EL Element 5

Each organic EL element 5 includes a positive electrode 20, an organic EL layer 30, and a negative electrode 34. The organic EL layer 30 is held between the positive electrode 20 and the negative electrode 34. In the present embodiment, layers provided between the positive electrode 20 and the negative electrode 34 are collectively referred to as an organic EL layer 30. The positive electrode 20, organic EL layer 30, and negative electrode 34 are layered in this order from the TFT substrate 10 side.

The positive electrode 20 is individually pattern formed in an island shape for each sub pixel 3, with the end of the positive electrode 20 covered by edge cover 23. Each positive electrode 20 is connected to the TFT 12 via contact holes provided in the passivation film 14 and the interlayer insulating film 15.

The edge cover 23 is disposed to partition the adjacent sub pixels 3. The edge cover 23 is an insulating layer, and for example, includes photosensitive resin. The edge cover 23 is formed to cover the end of the positive electrode 20. The edge cover 23 prevents a short circuit of the negative electrode 34 that may be caused by concentration of the electrodes or a decrease in thickness of the organic EL layer 30 at the end of the positive electrode 20. Moreover, the edge cover 23 also functions as a pixel separation film to prevent current leakage between the adjacent sub pixels 3.

The negative electrode 34 is a common electrode common to the sub pixels 3. The negative electrode 34 is common to the sub pixels 3 in all pixels 2. However, the present embodiment is not limited thereto, and the negative electrode 34 may be provided for each sub pixel 3 individually.

The circularly polarized light filter 35 is provided on the negative electrode 34 to cover the negative electrode 34. Additionally, a sealing layer 40 is provided on the circularly polarized light filter 35 to cover the circularly polarized light filter 35. The circularly polarized light filter 35 may be provided as required.

The sealing layer 40 protects the negative electrode 34 serving as the upper electrode, in addition to preventing external oxygen and moisture from infiltrating into each organic EL element 5. Note that the sealing layer 40 is provided to cover the negative electrode 34 in all organic EL elements 5.

### Positive Electrode 20 and Negative Electrode 34

The positive electrode 20 and the negative electrode 34 are a pair of electrodes. The positive electrode may function as an electrode for injecting holes (h⁺) into the organic EL layer 30. The negative electrode may function as an electrode for injecting electrons (e⁺) into the organic EL layer 30.

The shape, structure, size, or the like of the positive electrode and the negative electrode are not particularly limited and can be appropriately selected according to the application and object of the organic EL element 5.

In the present embodiment, the case will be described as an example in which, as illustrated in FIG. 1, the positive electrode 20 is patterned and disposed on the TFT substrate 10, the organic EL layer 30 is disposed between the positive electrode 20 and the negative electrode 34, and the negative electrode 34 is a negative electrode provided to be common to the sub pixels 3 in all pixels 2.

However, the present embodiment is not limited thereto, and the positive electrode 20 may be a negative electrode and the negative electrode 34 may be a positive electrode. In this case, the layering order or carrier mobility (carrier transport property, that is, hole transport property and electron transport property) of each functional layer configuring organic EL layer 30 are reversed. Similarly, the component materials of the positive electrode 20 and negative electrode 34 are also reversed.

Electrode materials capable of being employed as the positive electrode and the negative electrode are not particularly limited to a specific material, and, for example, known electrode materials may be employed therefor.

As the positive electrode, for example, metals such as gold (Au), platinum (Pt), and nickel (Ni), transparent electrode materials such as indium tin oxide (ITO), tin oxide (SnO₂), indium zinc oxide (IZO), gallium-added and zinc oxide (GZO) can be utilized.

The negative electrode preferably includes a material having a minor work function for injecting electrons into the light emitting layer 34. As the negative electrode, for example, metals such as lithium (Li), calcium (Ca), cerium (Ce), barium (Ba), and aluminum (Al), or alloys such as Ag (silver)-Mg (magnesium) alloy and Al-Li alloy containing these metals can be utilized.

The thickness of the positive electrode and negative electrode is not limited to a specific thickness, and the thickness capable may be similar to that of known ones.

The positive electrode 20 includes a configuration including the reflective electrode 21 and the transparent electrode 22 layered in this order from the TFT substrate 10 side. Note that the positive electrode 20 may be a single layer structure including a reflective electrode material.

Exemplary reflective electrode materials include a black electrode material such as tantalum (Ta) or carbon (C), a reflective metal electrode material such as Al, Ag, gold (Au), Al—Li alloy, Al-neodymium (Nd) alloy, or Al-silicon (Si) alloy.

As a transparent electrode material, for example, the transparent electrode material described above and the like may be used, and a semi-transparent electrode material may also be used, such as a thin film of Ag.

The reflective electrode 21 having the same film thickness for each sub pixel 3 is independently formed and is connected to the drain electrode of TFT 12 in each sub pixel 3.

The transparent electrode 22 also having the same film thickness for each sub pixel 3 is independently formed. The transparent electrode 22 is formed in each sub pixel 3 by the same manufacturing process.

### Organic EL Layer 30

The organic EL layer 30 includes a configuration, in which the hole injecting layer 24 (HIL), a common hole transport layer 25 (HTL), blue individual hole transport layer 26B (HTL-B)/green individual hole transport layer 26G (HTL-G)/red individual hole transport layer 26R (HTL-R), blue light emitting layer 27B (EML-B)/green light emitting layer 27G (EML-G)/red light emitting layer 27R (EML-R), a hole shielding layer 31 (HBL), an electron transport layer 32 (ETL), and an electron injecting layer 33 (EIL) are layered, as functional layers, in this order from the positive electrode 20 side.

In the organic EL display device 1, optical adjustment is carried out between the positive electrode 20 and the light emitting layer 27, or between the positive electrode 20 and the negative electrode 34, for each organic EL element 5, that is, for each sub pixel 3. As a result, a high definition image can be displayed. In the present embodiment, optical adjustment is carried out between the positive electrode 20 and the light emitting layer 27, or between the positive electrode 20 and the negative electrode 34, by changing the film thickness of the individual hole transport layer 26, for each organic EL element 5, that is, for each sub pixel 3.

The hole injecting layer 24, the common hole transport layer 25, the hole shielding layer 31, the electron transport layer 32, and the electron injecting layer 33 are formed as layers common to a plurality of pixels 2 across a plurality of pixels 2. Therefore, the hole injecting layer 24, the common hole transport layer 25, the hole shielding layer 31, the electron transport layer 32, and the electron injecting layer 33 are formed so as to be common to the sub pixels 3B, 3G, and 3R.

Hereinafter, in a case where the blue individual hole transport layer 26B, the green individual hole transport layer 26G, and the red individual hole transport layer 26R need not be discussed separately, the blue individual hole transport layer 26B, the green individual hole transport layer 26G, and the red individual hole transport layer 26R are collectively referred to as the individual hole transport layer 26 (HTL).

Moreover, in a case where the blue light emitting layer 27B, the green light emitting layer 27G, and the red light emitting layer 27R need not be discussed separately, the blue light emitting layer 27B, the green light emitting layer 27G, and the red light emitting layer 27R are collectively referred to as the light emitting layer 27.

The functional layers other than the common hole transport layer 25, the individual hole transport layer 26, and the light emitting layer 27 are not essential layers as the organic EL layer 30, but may be appropriately formed according to the required properties of the organic EL element 5. Hereinafter, each of the functional layers above will be described.

### Hole Injecting Layer 24 (HIL) and Common Hole Transport Layer 25 (HTL)

The hole injecting layer 24 is a layer including a material having a hole injecting property and a function to enhance the efficiency of hole injection to the light emitting layer 27. The hole injecting layer 24 is formed on the positive electrode 20 and the edge cover 23 and is common to each sub pixel 3. Moreover, the common hole transport layer 25 includes a material having a hole transport property and a function to enhance the efficiency of transporting a hole into light emitting layer 27. The hole is injected from the positive electrode 20 and transported via the hole injecting layer 24 into the common hole transport layer 25.

The hole injecting layer 24 and the common hole transport layer 25 may be formed as mutually independent layers or may be integrated together as a hole injection-cum-transport layer. Moreover, both the hole injecting layer 24 and the common hole transport layer 25 need not be provided. Only the common hole transport layer 25 may be provided.

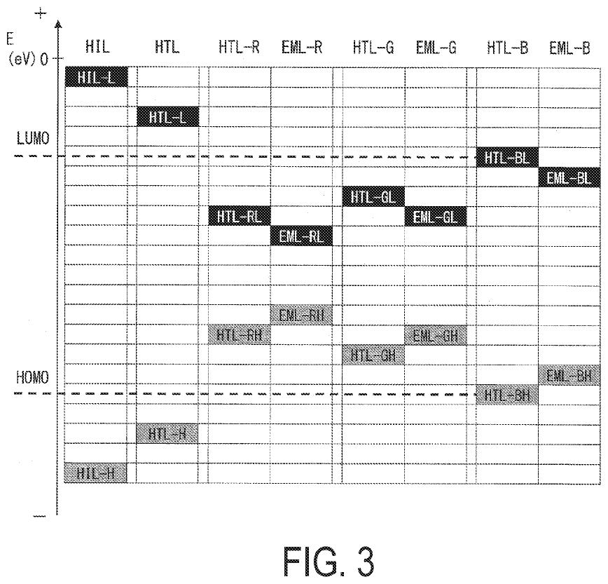

The known material as mentioned below can be used as the material of the hole injecting layer 24 and the common hole transport layer 25. Note that as mentioned later, the hole injecting layer 24 and the common hole transport layer 25 are configured such that the common hole transport layer 25 has a smaller HOMO-LUMO energy gap than the hole injecting layer 24. Note that this HOMO-LUMO energy gap will be mentioned later using FIG. 3.

Exemplary component materials of the hole injecting layer 24 and the common hole transport layer 25 include chain or heterocyclic conjugated monomers, oligomers, or polymers, such as naphthalene, anthracene, azatriphenylene, fluorenone, hydrazone, stilbene, triphenylene, benzine, styrylamine, triphenylamine, porphyrin, triazole, imidazole, oxadiazole, oxazole, polyaryl alkane, phenylenediamine, aryl amine, and derivatives thereof, a thiophene based compound, a polysilane based compound, a vinyl carbazole based compound, and an aniline based compound. More specifically, for example, N,N′-di(naphthalene-1-yl)-N,N′-diphenyl-benzidine (α-NPD), 2,3,6,7,10,11-hexacyano-1,4,5,8,9,12-hexaazatriphenylene (HAT-CN), 1,3-bis(carbazole-9-yl)benzene (mCP), di[4-(N,N-ditolyl-amino)-phenyl]cyclohexane (TAPC), 9,10-diphenylanthracene-2-sulfonate (DPAS), N,N′-diphenyl-N,N′-(4-(di(3-tolyl)amino)phenyl)-1,1′-biphenyl-4,4′-diamine (DNTPD), iridium(III)tris[N,N′-diphenylbenzoimidazole-2-ylidene-C2,C2′](Ir(dpbic)3), 4,4′,4″-tris-(N-carbazolyl)-triphenylamine (TCTA), 2,2-bis(p-trimellitic oxyphenyl)propanoic anhydride (BTPD), bis[4-(p,p-ditolylamino)phenyl]diphenylsilane (DTASi), or the like, are used.

Note that the hole injecting layer 24 and the common hole transport layer 25 may be an intrinsic material having a hole injecting property or an intrinsic material having a hole transport property, in which an impurity is not doped; alternatively, an impurity may be doped to increase the electrical conductivity, etc.

### Electron Transport Layer 32 and Electron Injecting Layer 33

The electron injecting layer 33 is a layer including a material with an electron injecting property and a function to enhance the efficiency of electron injection to the light emitting layer 27. Moreover, the electron transport layer 32 is a layer including a material having an electron transport property and a function to enhance the efficiency of electron transport to the light emitting layer 27.

The electron injecting layer 33 and the electron transport layer 32 are formed to be common to each sub pixel 3. The electron transport layer 32 is formed on each of the light emitting layer 27 and the common hole transport layer 25. The electron injecting layer 33 is formed on the electron transport layer 32.

Note that the electron injecting layer 33 and the electron transport layer 32 may be formed as mutually independent layers or may be integrated together as an electron injection-cum-transport layer. Moreover, both the electron injecting layer 33 and the electron transport layer 32 need not be provided. Only one of them, for example, only the electron transport layer 32 may be provided. Neither the electron injecting layer 33 nor the electron transport layer 32 may be provided.

The electron injecting layer 33 and the electron transport layer 32 may include known materials.

Exemplary component materials of electron injecting layer 33 and electron transport layer 32 include quinoline, perylene, phenanthroline, bisstyryl, pyrazine, triazole, oxazole, oxadiazole, fluorenone, derivatives and metal complexes thereof, lithium fluoride (LiF), etc.

More specific examples thereof include bis[(2-diphenylphosphoryl)phenyl]ether (DPEPO), 4,7-diphenyl-1,10-phenanthroline (Bphen), 3,3′-bis(9H-carbazole-9-yl)biphenyl (mCBP), 2,9-dimethyl-4,7-diphenyl-1,10-phenanthroline (BCP), 1,3,5-tris(N-phenylbenzoimidazole-2-yl)benzene (TPBI), 3-phenyl-4(1′-naphthyl)-5-phenyl-1,2,4-triazole (TAZ), 1,10-phenanthroline, Alq(tris(8-hydroxyquinoline)aluminum), LiF, etc.

### Sealing Layer 40

The sealing layer 40 is formed on the circularly polarized light filter 35. The sealing layer 40 seals the entire surface of the display region. The sealing layer 40 is employed for thin film sealing (TFE: Thin Film Encapsulation) on the organic EL layer 30, and thus the organic EL layer 30 is prevented from being deteriorated by moisture and oxygen infiltrated from outside.

As one example, the sealing layer 40 may have a three layer structure, in which an inorganic layer, an organic layer, and an inorganic layer are layered in this order. Examples of a material for the organic layer include organic insulating materials (resin materials) such as a polysiloxane, silicon oxide carbide (SiOC), an acrylate, a polyurea, parylene, a polyimide, and a polyamide. Examples of a material for the inorganic layer include inorganic insulating materials such as silicon nitride, silicon oxide, silicon oxynitride, and Al₂O₃. Note that the structure of the sealing layer 40 is not limited to the three layer structure described above.

### Individual Hole Transport Layer 26 and Light Emitting Layer 27

In each sub pixel 3, the island shaped individual hole transport layer 26 is formed on the common hole transport layer 25, while the light emitting layer 27 is formed on the individual hole transport layer 26.

In the blue sub pixel 3B, the blue individual hole transport layer 26B serving as the individual hole transport layer 26 is formed on the common hole transport layer 25, while the blue light emitting layer 27B emitting blue light is formed on the blue individual hole transport layer 26B. In the green sub pixel 3G, the green individual hole transport layer 26G serving as the individual hole transport layer 26 is formed on the common hole transport layer 25, while the green light emitting layer 27G emitting green light is formed on the green individual hole transport layer 26G. In the red sub pixel 3R, the red individual hole transport layer 26R serving as the individual hole transport layer 26 is formed on the common hole transport layer 25, while the red light emitting layer 27R emitting red light is formed on the red individual hole transport layer 26R.

A hole injected from the positive electrode 20 into the light emitting layer 27, as well as an electron injected from the negative electrode 34 into the light emitting layer 27, are recombined in the light emitting layer 27 to form an exciton. The formed exciton emits light during decay from the excited state to the ground state. As a result, the blue light emitting layer 27B emits blue light, the green light emitting layer 27G emits green light, and the red light emitting layer 27R emits red light.

Here, the energy required for this recombination is different among the blue light emitting layer 27B, the green light emitting layer 27G, and the red light emitting layer 27R. Therefore, with the mere provision of the common hole transport layer 25 common to the blue light emitting layer 27B, the green light emitting layer 27G, and the red light emitting layer 27R, a hole cannot be injected according to each independent material and property of the blue light emitting layer 27B, the green light emitting layer 27G, and the red light emitting layer 27R.

A hole not injected into the light emitting layer 27 may remain in the common hole transport layer 25. Thus, the electron is prevented from recombining in the light emitting layer 27, and the amount of the electrons injected from the electron transport layer 32 into the light emitting layer 27 decreases, with excess electrons remaining in electron transport layer 32.

Then, in the organic EL display device 1 according to the present embodiment, the individual hole transport layer 26, in addition to the common hole transport layer 25, is further individually formed between the common hole transport layer 25 and the light emitting layer 27 in each sub pixel 3.

FIG. 3 is a view illustrating a HOMO-LUMO energy gap in a sub pixel of the organic EL display device according to Embodiment 1 of the disclosure. Each energy level value illustrated in FIG. 3 is defined as follows. Note that in the present embodiment, each energy level value is a negative value.

The energy level value of the Lowest Unoccupied Molecular Orbital (LUMO) of the hole injecting layer 24 (HIL) is defined as HIL-L, while the energy level value of the Highest Occupied Molecular Orbital (HOMO) thereof is defined as HIL-H.

The energy level value of the Lowest Unoccupied Molecular Orbital (LUMO) of the common hole transport layer 25 (HTL) is defined as HTL-L, while the energy level value of the Highest Occupied Molecular Orbital (HOMO) thereof is defined as HTL-H.

The energy level value of the lowest unoccupied molecular orbital (LUMO) of the red individual hole transport layer 26R (HTL-R) is defined as HTL-RL, while the energy level value of the highest occupied molecular orbital (HOMO) thereof is defined as HTL-RH.

The energy level value of the Lowest Unoccupied Molecular Orbital (LUMO) of the red light emitting layer 27R (EML-R) is defined as EML-RL, while the energy level value of the Highest Occupied Molecular Orbital (HOMO) is defined as EML-RH.

The energy level value of the Lowest Unoccupied Molecular Orbital (LUMO) of the green individual hole transport layer 26G (HTL-G) is defined as HTL-GL, while the energy level value of the Highest Occupied Molecular Orbital (HOMO) thereof is defined as HTL-GH.

The energy level value of the Lowest Unoccupied Molecular Orbital (LUMO) of the green light emitting layer 27G (EML-G) is defined as EML-GL, while the energy level value of the Highest Occupied Molecular Orbital (HOMO) thereof is defined as EML-GH.

The energy level value of the Lowest Unoccupied Molecular Orbital (LUMO) of the blue individual hole transport layer 26B (HTL-B) is defined as HTL-BL, while the energy level value of the Highest Occupied Molecular Orbital (HOMO) thereof is defined as HTL-BH.

The energy level value of the Lowest Unoccupied Molecular Orbital (LUMO) of the blue light emitting layer 27B (EML-B) is defined as EML-BL, while the energy level value of the Highest Occupied Molecular Orbital (HOMO) thereof is defined as EML-BH.

Moreover, the difference between the energy level value of the Lowest Unoccupied Molecular Orbital (LUMO) and the energy level value of the Highest Occupied Molecular Orbital (HOMO) is referred to as a HOMO-LUMO energy gap.

Regarding HIL and HTL, the value of HTL-L is smaller than that of HIL-L, while the value of HTL-H is larger than that of HIL-H. HTL has a smaller HOMO-LUMO energy gap than HIL.

Regarding HTL and EML-B, the value of EML-BL is smaller than that of HTL-L, while the value of EML-BH is larger than that of HTL-H. EML-B has a smaller HOMO-LUMO energy gap than HTL.

Regarding EML-B and EML-G, the value of EML-GL is smaller than that of EML-BL, while the value of EML-GH is larger than that of EML-BH. EML-G has a smaller HOMO-LUMO energy gap than EML-B.

Regarding EML-G and EML-R, the value of EML-RL is smaller than that of EML-GL, while the value of EML-RH is larger than that of HTL-GH. EML-R has a smaller HOMO-LUMO energy gap than EML-G.

Additionally, the individual hole transport layer 26 formed in each sub pixel 3 is configured as follows.

Regarding HTL-B, HTL-BL is larger than EML-BL but smaller than HIL-L, while HTL-BH is smaller than EML-BH but larger than HIL-H.

Regarding HTL-G, HTL-GL is larger than EML-GL but smaller than HTL-BL, while HTL-GH is smaller than EML-GH but larger than HIL-BH.

Regarding HTL-R, HTL-RL is larger than EML-RL but smaller than HTL-GL, while HTL-RH is smaller than EML-RH but larger than HIL-GH.

The relationships among HOMOs can be represented as follows.

|HIL-H|>|HTL-H|>|HTL-BH|>|EML-BH|>|HTL-GH|>|EML-GH|>|HTL-RH|>|EML-RH| (Relationship 1)

The relationships among LUMOs can be represented as follows.

|HIL-L|<|HTL-L|<|HTL-BL|<|EML-BL|<|HTL-GL|<|EML-GL|<|HTL-RL|<|EML-RL| (Relationship 2)

In the organic EL display device 1, the individual hole transport layer 26 is formed to satisfy Relationships (1) and (2) above.

As described above, the energy level value (HTL-BL, HTL-GL, HTL-RL) of the lowest unoccupied molecular orbital (LUMO) of the individual hole transport layer 26 is smaller than the energy level value (HTL-L) of the lowest unoccupied molecular orbital (LUMO) of the common hole transport layer 25, but larger than the energy level value (EML-BL, EML-GL, EML-RL) of the lowest unoccupied molecular orbital (LUMO) of the light emitting layers 27B, 27G, and 27R in the sub pixel 3.

As a result, in each sub pixel 3, the individual hole transport layer 26 is individually disposed, wherein the energy level value of the lowest unoccupied molecular orbital (LUMO) is smaller than the energy level value of the lowest unoccupied molecular orbital (LUMO) of the common hole transport layer 25, but larger than the energy level value of the lowest unoccupied molecular orbital (LUMO) of the light emitting layer 27 in the sub pixel 3. As a result, a hole can be efficiently injected into the light emitting layer 27 for each sub pixel 3. Consequently, the light emitting layer 27 can be efficiently emitted for each sub pixel 3.

Additionally, in each sub pixel 3, the energy level value (HIL-BH, HIL-GH, HIL-RH) of the highest occupied molecular orbital (HOMO) of the individual hole transport layer 26 is larger than the energy level value (HTL-H) of the highest occupied molecular orbital (HOMO) of the common hole transport layer 25, but smaller than the energy level value (EML-BH, EML-GH, EML-RH) of the highest occupied molecular orbital (HOMO) of the light emitting layers 27B, 27G, and 27R in the sub pixel 3. As a result, a hole can be efficiently injected into the light emitting layer 27 for each sub pixel 3. Therefore, the light emitting layer 27 can be efficiently emitted for each sub pixel 3.

Moreover, the HOMO-LUMO energy gap of the blue individual hole transport layer 26B is largest among the individual hole transport layers 26 disposed in the sub pixel 3 in the pixel 2.

Specifically, because the HOMO-LUMO energy gap of the blue individual hole transport layer 26B is larger than the HOMO-LUMO energy gap of each of the green individual hole transport layer 26G and the red individual hole transport layer 26R, a hole can be efficiently injected into the blue light emitting layer 27B.

Further, the HOMO-LUMO energy gap of the red individual hole transport layer 26R is smallest among the individual hole transport layers 26 disposed in the sub pixel 3 in the pixel 2.

Specifically, because the HOMO-LUMO energy gap of the red individual hole transport layer 26R is smaller than the HOMO-LUMO energy gap of the green individual hole transport layer 26G, a hole can be efficiently injected into each of the red light emitting layer 27R and the blue light emitting layer 27B.

Additionally, the HOMO-LUMO energy gap of the green individual hole transport layer 26G is larger than the HOMO-LUMO energy gap of the red individual hole transport layer 26R, but smaller than the HOMO-LUMO energy gap of the blue individual hole transport layer 26B. As a result, a hole can be efficiently injected into the green light emitting layer 27G.

In addition, a film thickness t1 of the blue individual hole transport layer 26B is thinnest among the individual hole transport layers 26 disposed in the sub pixel 3 in the pixel 2.

Specifically, because the film thickness t1 of the blue individual hole transport layer 26B is thinnest among the film thickness t1 of the blue individual hole transport layer 26B, the film thickness t2 of the green individual hole transport layer 26G, and the film thickness t3 of the red individual hole transport layer 26R, the blue light emitting layer 27B can efficiently emit light.

Further, the film thickness t3 of the red individual hole transport layer 26R is thickest among the individual hole transport layers 26 disposed in the sub pixel 3 in the pixel 2.

Specifically, because the film thickness t3 of the red individual hole transport layer 26R is thicker than the film thickness t2 of the green individual hole transport layer 26G, both the green light emitting layer 27G and the red light emitting layer 27R can efficiently emit light.

Additionally, the film thickness t2 of the green individual hole transport layer 26G is thinner than the film thickness t3 of the red individual hole transport layer 26R, but thicker than the film thickness t1 of the blue individual hole transport layer 26B. As a result, a hole can be efficiently injected into the green light emitting layer 27G.

After forming the common hole transport layer 25, this individual hole transport layer 26 can be patterned in each sub pixel 3 by vapor deposition by color. That is, the individual hole transport layer 26 is individually sequentially patterned in each sub pixel 3B, 3G, and 3R using a mask.

Note that the configuration is not preferable in which, among the common hole transport layer 25 and the individual hole transport layer 26, the common hole transport layer 25 is omitted, while only the individual hole transport layer 26 is provided. This is because the individual hole transport layers 26 need to be sequentially patterned for thee colors, and the time required to pattern the common hole transport layer 25 is as three times as long. Thus, the production efficiency may degrade.

Examples of the materials for the light emitting layer 27 and the individual hole transport layer 26 include the following and they can satisfy Relationships (1) and (2) above.

Examples of the blue individual hole transport layer 26B may include HAT-CN, and CuPc.

Examples of the green individual hole transport layer 26G may include a-NPD.

Examples of the red individual hole transport layer 26R may include PCzPA.

Examples of the blue light emitting layer 27B may include TAPC, and TAZ.

Examples of the green light emitting layer 27G may include α-NPD, and BCP.

Examples of the red light emitting layer 27R may include TPD, and TPBI.

Moreover, the film thickness t1 of the blue individual hole transport layer 26B may be approximately 10 nm, for example. The film thickness t2 of the green individual hole transport layer 26G may be approximately 50 nm, for example. The film thickness t3 of the red individual hole transport layer 26R may be approximately 100 nm, for example.

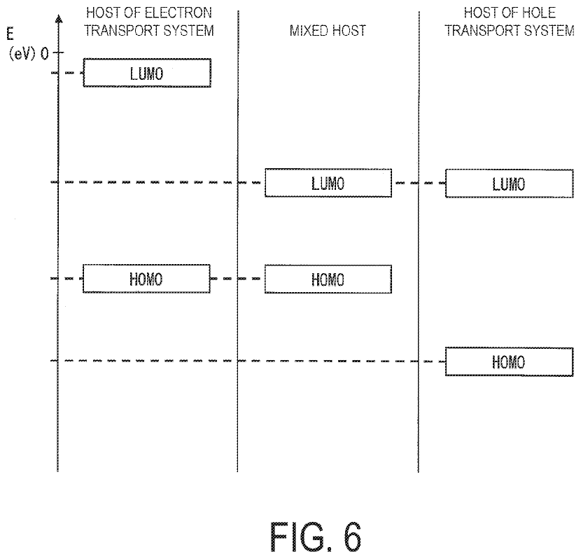

FIG. 6 is a view describing a HOMO-LUMO energy gap in a light emitting layer of the organic EL display device according to Embodiment 1 of the disclosure.

A mixed host obtained by mixing the host material of a hole transport system with the host material of an electron transport system, as illustrated in FIG. 6, has a small energy level value of the lowest unoccupied molecular orbital (LUMO), but has a large energy level value of the highest occupied molecular orbital (HOMO). That is, by mixing the host material of the hole transport system with the host material of the electron transport system, a mixed host having a small HOMO-LUMO energy gap can be obtained. Such a mixed host can be included in light emitting layer 27, and the light emitting layer 27 having a small HOMO-LUMO energy gap can be obtained. As a result, the light emitting layer 27 satisfying Relationships (1) and (2) can be easily obtained.

Examples of the host materials of such a transport system may include α-NPD. Moreover, examples of the host materials of such an electron transport system may include BCP.

Note that the mixed host need not be included in all the light emitting layers of the red light emitting layer 27R, the green light emitting layer 27G, and the blue light emitting layer 27B. For example, a configuration may be used in which each of the red light emitting layer 27R and the green light emitting layer 27G includes the mixed host, while the blue light emitting layer 27B does not include the mixed host.

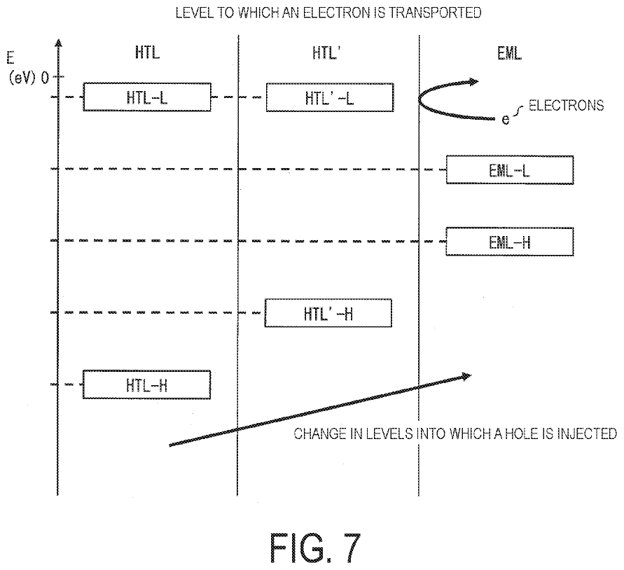

FIG. 7 is a view describing a HOMO-LUMO energy gap of HTL, HTL′, and EML of the organic EL display device 1 according to Embodiment 1 of the disclosure.

The energy level value of the Lowest Unoccupied Molecular Orbital (LUMO) of the individual hole transport layer 26 (HTL′) is defined as HTL′-L, while the energy level value of the Highest Occupied Molecular Orbital (HOMO) of the individual hole transport layer 26 (HTL′) is defined as HTL′-H.

The energy level value of the Lowest Unoccupied Molecular Orbital (LUMO) of the light emitting layer 27 (EML) is defined as EML-L, while the energy level value of the Highest Occupied Molecular Orbital (HOMO) of the light emitting layer 27 (EML) is defined as EML-H.

It is not problematic as long as the individual hole transport layer 26 (HTL′) can prevent an electron from entering from the light emitting layer 27 (EML) into the hole transport layer 26 (HTL).

Therefore, HTL-L≥HTL′-L is acceptable.

Moreover, any value of HTL′-L is acceptable as long as the value od HTL′-L satisfies the relationship HTL-L>>EML-L.

### Embodiment 2

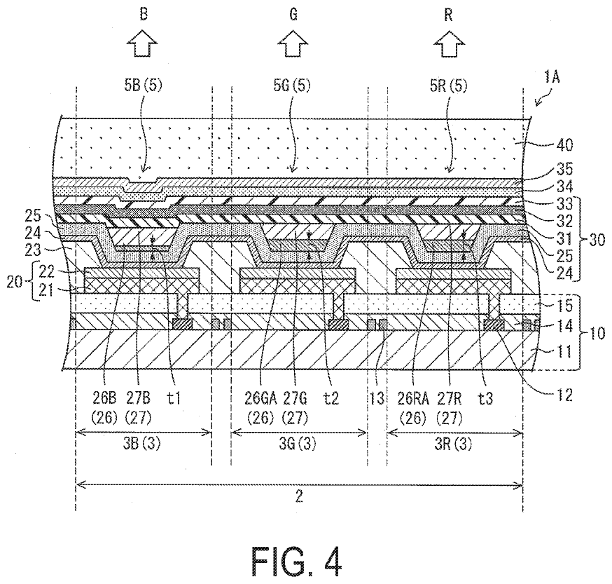

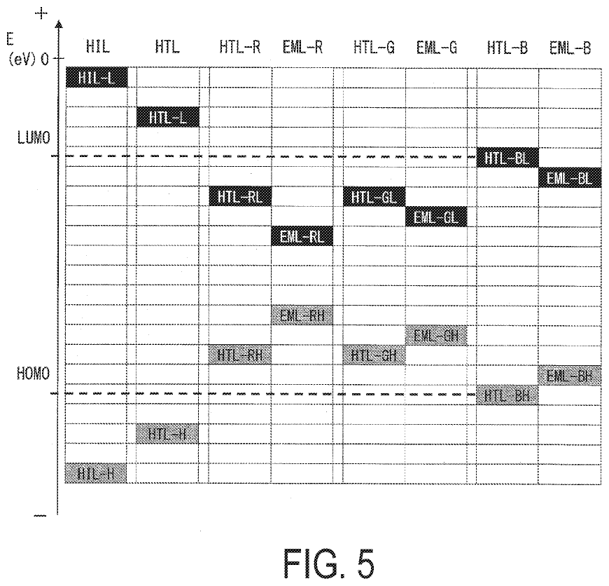

A following description is regarding Embodiment 2 of the disclosure, with reference to FIGS. 4 and 5. Note that for convenience of description, members having the same function as the members stated in Embodiment 1 are appended with the same reference symbols, with the description thereof omitted.

FIG. 4 is a cross-sectional view illustrating the configuration of the organic EL display device 1A according to Embodiment 2 of the disclosure.

The organic EL display device 1A is configured such that, in the organic EL display device 1 (see FIG. 1), the green individual hole transport layer 26G is replaced with the green individual hole transport layer 26GA, while the red individual hole transport layer 26R is replaced with the red individual hole transport layer 26RA. The configurations of the other parts of the organic EL display device 1A are the same as those of the organic EL display device 1.

FIG. 5 is a view illustrating a HOMO-LUMO energy gap in the sub pixel of the organic EL display device according to Embodiment 2 of the disclosure.

As illustrated in FIGS. 4 and 5, the organic EL display device 1A is configured to satisfy Relationships (3) and (4) below.

That is, the relationships among HOMOs can be represented as follows.

|HIL-H|>|HTL-H|>|HTL-BH|>|EML-BH|>|HTL-GH|=|HTL-RH|>|EML-GH|>|EML-RH| (Relationship 3)

The relationships among LUMOs can be represented as follows.

|HIL-L|<|HTL-L|<|HTL-BL|<|EML-BL|<|HTL-GL|=|HTL-RL|<|EML-GL|<|EML-RL| (Relationship 4)

As described above, the HOMO-LUMO energy gap of the red individual hole transport layer 26RA is equal to the HOMO-LUMO energy gap of the green individual hole transport layer 26GA.

Moreover, the film thickness t2 of the green individual hole transport layer 26GA is equal to the film thickness t3 of the red individual hole transport layer 26RA.

As a result, the red individual hole transport layer 26R and the green individual hole transport layer 26G can include the same material. As a result, the production efficiency can be improved.

Exemplary materials of the green individual hole transport layer 26GA may include CuPc, and TPD.

Exemplary materials of the red individual hole transport layer 26RA may include TAPC, and α-NPD.

### Embodiment 3

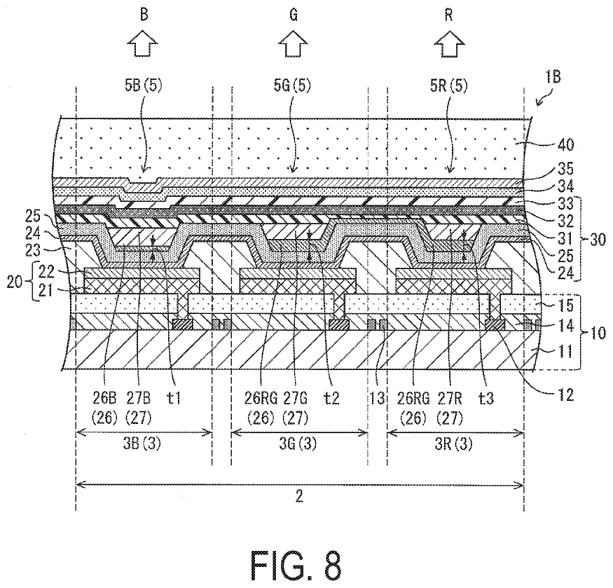

A following description is regarding Embodiment 3 of the disclosure, with reference to FIG. 8. Note that for convenience of description, members having the same function as the members stated in Embodiments 1 and 2 are appended with the same reference symbols, with the description thereof omitted.

FIG. 8 is a cross sectional view illustrating the configuration of the organic EL display device 1B according to Embodiment 3 of the disclosure.

The organic EL display device 1B is configured such that, in the organic EL display device 1A (see FIG. 4), the green individual hole transport layer 26GA and the red individual hole transport layer 26RA are replaced with the common individual hole transport layer 26RG. The configurations of the other parts of the organic EL display device 1B are the same as those of the organic EL display device 1A.

The common individual hole transport layer 26RG is the individual hole transport layer 26 disposed across the green sub pixel 3G and the red sub pixel 3R to be common to the green sub pixel 3G and the red sub pixel 3R, excluding the blue sub pixel 3B, among the plurality of sub pixels 3. Note that as the individual hole transport layer 26, the blue individual hole transport layer 26B different from the common individual hole transport layer 26RG is disposed in the blue sub pixel 3B.

The common individual hole transport layer 26RG has a larger HOMO-LUMO energy gap than a light emitting layer which has the largest HOMO-LUMO energy gap among the light emitting layers included in the plurality of sub pixels, in which the common individual hole transport layer 26RG is disposed. In the present embodiment, the common individual hole transport layer 26RG is configured such that the LUMO has a larger energy level value than LUMO of EML-GL, while the HOMO has a smaller energy level value than HOMO of EML-GH.

The film thickness t2 of the common individual hole transport layer 26RG disposed in the green sub pixel 3G is equal to the film thickness t3 of the common individual hole transport layer 26RG disposed in the red sub pixel 3R.

According to the configuration above, the individual hole transport layer disposed in the other sub pixels described above can include the same material. As a result, the production efficiency can be improved.

Note that the film thicknesses t2 and t3 are larger than the film thickness t1 of the blue individual hole transport layer 26B.

### Supplement

In the organic EL display devices 1 and 1A according to the first aspect of the disclosure, the pixels 2 having a plurality of sub pixels 3 emitting light of different colors are arranged on the display region 1 in a matrix, the organic EL display devices 1 and 1A including: the light emitting layer 27 individually disposed in each sub pixel 3 and emitting light of a different color for each sub pixel 3; the positive electrode 20 and the negative electrode 34 arranged facing each other, the light emitting layer 27 being disposed between the positive electrode 20 and the negative electrode 34; and the common hole transport layer 25 common to the sub pixel 3, the common hole transport layer 25 being disposed between the positive electrode 20 and the light emitting layer 27, wherein the individual hole transport layer 26 is further individually disposed in each sub pixel 3, between the common hole transport layer 25 and the light emitting layer 27 for each sub pixel 3, and an energy level value (HTL-BL, HTL-GL, HTL-RL) of a Lowest Unoccupied Molecular Orbital (LUMO) of the individual hole transport layer 26 is smaller than an energy level value (HTL-L) of a Lowest Unoccupied Molecular Orbital (LUMO) of the common hole transport layer 25 and greater than an energy level value (EML-BL, EML-GL, EML-RL) of a Lowest Unoccupied Molecular Orbital (LUMO) of the light emitting layers 27B, 27G, and 27R in the sub pixels 3.

According to the configuration above, in each sub pixel, the individual hole transport layer is individually disposed, wherein the energy level value of the lowest unoccupied molecular orbital of the individual hole transport layer is smaller than the energy level value of the lowest unoccupied molecular orbital of the common hole transport layer, but larger than the energy level value of the lowest unoccupied molecular orbital of the light emitting layer in the sub pixel. Thus, a hole can be efficiently injected into the light emitting layer for each sub pixel. Therefore, the light emitting layer can efficiently emit light for each sub pixel.

In the organic EL display devices 1 and 1A according to the second aspect of the disclosure, referring to the first aspect, in each sub pixel 3, an energy level value (HIL-BH, HIL-GH, HIL-RH) of a Highest Occupied Molecular Orbital (HOMO) of the individual hole transport layer 26 is preferably larger than an energy level value (HTL-H) of a Highest Occupied Molecular Orbital (HOMO) of the common hole transport layer 25, but preferably smaller than an energy level value (EML-BH, EML-GH, EML-RH) of a Highest Occupied Molecular Orbital (HOMO) of the light emitting layers 27B, 27G, and 27R in the sub pixel 3.

According to the configuration above, a hole can be efficiently injected into the light emitting layer for each sub pixel. Therefore, the light emitting layer can efficiently emit light for each sub pixel.

In the organic EL display devices 1, 1A, and 1B according to the third aspect of the disclosure, a film thickness of individual hole transport layer 26 is different for each sub pixel 3, providing optical adjustment between the positive electrode 20 and the light emitting layer 27, or between the positive electrode 20 and the negative electrode 34. According to the configuration above, a high definition image can be displayed.

In the organic EL display devices 1, 1A, and 1B according to the fourth aspect of the disclosure, referring to the first to third aspects, the plurality of the sub pixels 3 of the pixels 2 may include a blue sub pixel 3B, wherein the blue light emitting layer 27B serving as light emitting layer 27 emitting blue light is disposed in the blue sub pixel.

In the organic EL display devices 1, 1A, and 1B according to the fifth aspect of the disclosure, referring to the fourth aspect, a difference between the energy level value of the lowest unoccupied molecular orbital (LUMO) and the energy level value of the highest occupied molecular orbital (HOMO) is a HOMO-LUMO energy gap, and the HOMO-LUMO energy gap of the blue individual hole transport layer 26B serving as the individual hole transport layer 26 disposed in the blue sub pixel 3B may be largest among the plurality of sub pixels. According to the configuration above, a hole can be efficiently injected into the blue light emitting layer.

In the organic EL display devices 1, 1A, and 1B according to the sixth aspect of the disclosure, referring to the fifth aspect above, a film thickness t1 of the blue individual hole transport layer 26B serving as the individual hole transport layer 26 disposed in the blue sub pixel 3B may be thinnest among the plurality of sub pixels 3. According to the configuration above, a hole can be efficiently injected into the blue light emitting layer.

In the organic EL display devices 1, 1A, and 1B according to seventh aspect of the disclosure, referring to the first to sixth aspects above, the plurality of the sub pixels of the pixels may include the red sub pixel, wherein the red light emitting layer serving as the light emitting layer emitting red light is disposed in the red sub pixel.

In the organic EL display devices 1, 1A, and 1B according to eighth aspect of the disclosure, referring to the seventh aspect above, the difference between the energy level value of the lowest unoccupied molecular orbital and the energy level value of the highest occupied molecular orbital is a HOMO-LUMO energy gap, and the HOMO-LUMO energy gap of the red individual hole transport layer 26R serving as the individual hole transport layer 26 disposed in the red sub pixel 3R may be smallest among the plurality of sub pixels 3. According to the configuration above, a hole can be efficiently injected into the red light emitting layer.

In the organic EL display devices 1, 1A, and 1B according to ninth aspect of the disclosure, referring to the seventh or eighth aspect above, a film thickness t3 of the red individual hole transport layer 26R serving as the individual hole transport layer 26 disposed in the red sub pixel 3R may be thickest among the plurality of sub pixels 3. According to the configuration above, a hole can be efficiently injected into the red light emitting layer.

In the organic EL display devices 1, 1A, and 1B according to tenth aspect of the disclosure, referring to the seventh or eighth aspect, the plurality of the sub pixels 3 of the pixels 2 may include a green sub pixel 3G, wherein the green light emitting layer 27G serving as the light emitting layer 27 emitting green light is disposed in the green sub pixel.

In the organic EL display devices 1, 1A, and 1B according to eleventh aspect of the disclosure, referring to the tenth aspect above, the difference between the energy level value of the lowest unoccupied molecular orbital and the energy level value of the highest occupied molecular orbital is a HOMO-LUMO energy gap, and the HOMO-LUMO energy gap of the green individual hole transport layer 26G serving as the individual hole transport layer 26 disposed in the green sub pixel 3G may be larger than the HOMO-LUMO energy gap of the red individual hole transport layer 26R serving as the individual hole transport layer 26 disposed in the red sub pixel 3R, among the plurality of sub pixels 3. According to the configuration above, a hole can be efficiently injected into the red light emitting layer and the green light emitting layer.

In the organic EL display device 1 according to the twelfth aspect of the disclosure, referring to the tenth aspect above, a film thickness t2 of the green individual hole transport layer 26G serving as the individual hole transport layer 26 disposed in the green sub pixel 3G may be thinner than the film thickness t3 of the red individual hole transport layer 26R serving as the individual hole transport layer 26 disposed in the red sub pixel 3R, among the plurality of sub pixels 3. According to the configuration above, a hole can be efficiently injected into the red light emitting layer and the green light emitting layer.

In the organic EL display devices 1A and 1B according to the thirteenth aspect of the disclosure, referring to the tenth aspect above, the difference between the energy level value of the lowest unoccupied molecular orbital and the energy level value of the highest occupied molecular orbital is a HOMO-LUMO energy gap, and the HOMO-LUMO energy gap of the green individual hole transport layer 26G serving as the individual hole transport layer 26 disposed in the green sub pixel 3G may be equal to the HOMO-LUMO energy gap of the red individual hole transport layer 26R serving as the individual hole transport layer 26R disposed in the red sub pixel 3R, among the plurality of sub pixels 3. According to the configuration above, the red individual hole transport layer and the green individual hole transport layer can include the same material. As a result, the production efficiency can be improved.

In the organic EL display devices 1A and 1B according to the fourteenth aspect of the disclosure, referring to the tenth or thirteenth aspect above, the film thickness t2 of the green individual hole transport layer 26G serving as the individual hole transport layer 26 disposed in the green sub pixel 3G may be equal to the film thickness t3 of the red individual hole transport layer 26R serving as the individual hole transport layer 26 disposed in the red sub pixel 3R, among the plurality of sub pixels 3.

According to the configuration above, the red individual hole transport layer and the green individual hole transport layer can include the same material. As a result, the production efficiency can be improved.

In the organic EL display device 1B according to fifteenth aspect of the disclosure, referring to the fourth to sixth aspects above, the individual hole transport layer 26 disposed in the sub pixels other than the blue sub pixel 3B may be common across the plurality of the sub pixels other than the blue sub pixel, among the plurality of sub pixels 3. According to the configuration above, the individual hole transport layer arranged in the other sub pixels described above can include the same material. As a result, the production efficiency can be improved.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SYMBOLS LIST

1a Display region
1, 1A, 1B Organic EL display devices
3 sub pixel
3B Blue sub pixel
3G Green sub pixel
3R Red sub pixel
5 Organic EL element
5B Blue organic EL element
5G Green organic EL element
5R Red organic EL element
10 TFT substrate
11 Support body
12 TFT
13 Wiring line
14 Passivation film
15 Interlayer insulating film
20 Positive electrode
21 Reflective electrode
22 Transparent electrode
23 Edge cover
24 Hole injecting layer
25 Common hole transport layer
25 Hole transport layer
26 Individual hole transport layer
26B Blue individual hole transport layer (individual hole transport layer)
26G, 26GA Green individual hole transport layer (individual hole transport layer)
26R, 26RA Red individual hole transport layer (individual hole transport layer)
26RG Common individual hole transport layer (individual hole transport layer)
27 Light emitting layer
27B Blue light emitting layer
27G Green light emitting layer
27R Red light emitting layer
30 Organic EL layer
31 Hole shielding layer
32 Electron transport layer
33 Electron injecting layer
34 Negative electrode
35 Circularly polarized light filter
40 Sealing layer

1. (canceled)

2. An organic EL display device comprising pixels arranged on a display region in a matrix, the pixels comprising a plurality of sub pixels emitting light of different colors, the organic EL display device comprising:
a light emitting layer individually disposed in each sub pixel and emitting light of a different color for each sub pixel;
a positive electrode and a negative electrode arranged facing each other, the light emitting layer being disposed between the positive electrode and the negative electrode; and
a common hole transport layer common to each sub pixel, the common hole transport layer being disposed between the positive electrode and the light emitting layer,
wherein an individual hole transport layer is further individually disposed in each sub pixel, between the common hole transport layer and the light emitting layer for each sub pixel, and
an energy level value of a lowest unoccupied molecular orbital of the individual hole transport layer is smaller than an energy level value of a lowest unoccupied molecular orbital of the common hole transport layer for each sub pixel and greater than an energy level value of a lowest unoccupied molecular orbital of the light emitting layer in the sub pixel, and
in each sub pixel, an energy level value of a highest occupied molecular orbital of the individual hole transport layer is greater than an energy level value of a highest occupied molecular orbital of the common hole transport layer, and smaller than an energy level value of a highest occupied molecular orbital of the light emitting layer in the sub pixel.

3. The organic EL display device according to claim 2, wherein a film thickness of the individual hole transport layer is different for each sub pixel, providing optical adjustment between the positive electrode and the light emitting layer or between the positive electrode and the negative electrode.

4. The organic EL display device according to claim 2, wherein the plurality of sub pixels of the pixels comprise a blue sub pixel, a blue light emitting layer serving as the light emitting layer emitting blue light being disposed in the blue sub pixel.

5. The organic EL display device according to claim 4, wherein a difference between an energy level value of a lowest unoccupied molecular orbital and an energy level value of a highest occupied molecular orbital is a HOMO-LUMO energy gap, and the HOMO-LUMO energy gap of a blue individual hole transport layer serving as the individual hole transport layer disposed in the blue sub pixel is largest among the plurality of sub pixels.

6. The organic EL display device according to claim 4, wherein a film thickness of a blue individual hole transport layer serving as the individual hole transport layer disposed in the blue sub pixel is thinnest among the plurality of sub pixels.

7. The organic EL display device according to claim 2, wherein the plurality of sub pixels of the pixels comprise a red sub pixel, a red light emitting layer serving as the light emitting layer emitting red light being disposed in the red sub pixel.

8. The organic EL display device according to claim 7, wherein a difference between an energy level value of a lowest unoccupied molecular orbital and an energy level value of a highest occupied molecular orbital is a HOMO-LUMO energy gap, and the HOMO-LUMO energy gap of a red individual hole transport layer serving as the individual hole transport layer disposed in the red sub pixel is smallest among the plurality of sub pixels.

9. The organic EL display device according to claim 7, wherein a film thickness of a red individual hole transport layer serving as the individual hole transport layer disposed in the red sub pixel is thickest among the plurality of sub pixels.

10. The organic EL display device according to claim 7, wherein the plurality of sub pixels of the pixels comprise a green sub pixel, a green light emitting layer serving as the light emitting layer emitting green light being disposed in the green sub pixel.

11. The organic EL display device according to claim 10, wherein a difference between an energy level value of a lowest unoccupied molecular orbital and an energy level value of a highest occupied molecular orbital is a HOMO-LUMO energy gap, and the HOMO-LUMO energy gap of a green individual hole transport layer serving as the individual hole transport layer disposed in the green sub pixel is greater than the HOMO-LUMO energy gap of a red individual hole transport layer serving as the individual hole transport layer disposed in the red sub pixel.

12. The organic EL display device according to claim 10, wherein a film thickness of a green individual hole transport layer serving as the individual hole transport layer disposed in the green sub pixel is thinner than a film thickness of a red individual hole transport layer serving as the individual hole transport layer disposed in the red sub pixel among the plurality of sub pixels.

13. The organic EL display device according to claim 10, wherein a difference between an energy level value of a lowest unoccupied molecular orbital and an energy level value of a highest occupied molecular orbital is a HOMO-LUMO energy gap, and the HOMO-LUMO energy gap of a green individual hole transport layer serving as the individual hole transport layer disposed in the green sub pixel is equal to the HOMO-LUMO energy gap of a red individual hole transport layer serving as the individual hole transport layer disposed in the red sub pixel.

14. The organic EL display device according to claim 10, wherein a film thickness of a green individual hole transport layer serving as the individual hole transport layer disposed in the green sub pixel is equal to the film thickness of a red individual hole transport layer serving as the individual hole transport layer disposed in the red sub pixel among the plurality of sub pixels.

15. The organic EL display device according to claim 4, wherein the individual hole transport layer disposed in a sub pixel other than the blue sub pixel is common across a plurality of the sub pixels other than the blue sub pixel among the plurality of sub pixels.

16. An organic EL display device comprising pixels arranged on a display region in a matrix, the pixels comprising a plurality of sub pixels emitting light of different colors, the organic EL display device comprising:
a light emitting layer individually disposed in each sub pixel and emitting light of a different color for each sub pixel;
a positive electrode and a negative electrode arranged facing each other, the light emitting layer being disposed between the positive electrode and the negative electrode; and
a common hole transport layer common to each sub pixel, the common hole transport layer being disposed between the positive electrode and the light emitting layer,
wherein an individual hole transport layer is further individually disposed in each sub pixel, between the common hole transport layer and the light emitting layer for each sub pixel, and
an energy level value of a lowest unoccupied molecular orbital of the individual hole transport layer is smaller than an energy level value of a lowest unoccupied molecular orbital of the common hole transport layer for each sub pixel and greater than an energy level value of a lowest unoccupied molecular orbital of the light emitting layer in the sub pixel, and the plurality of sub pixels of the pixels comprise a blue sub pixel, a blue light emitting layer serving as the light emitting layer emitting blue light being disposed in the blue sub pixel, and
a difference between an energy level value of a lowest unoccupied molecular orbital and an energy level value of a highest occupied molecular orbital is a HOMO-LUMO energy gap, and the HOMO-LUMO energy gap of a blue individual hole transport layer serving as the individual hole transport layer disposed in the blue sub pixel is largest among the plurality of sub pixels.

17. The organic EL display device according to claim 16, wherein a film thickness of the individual hole transport layer is different for each sub pixel, providing optical adjustment between the positive electrode and the light emitting layer or between the positive electrode and the negative electrode.

18. The organic EL display device according to claim 16, wherein a film thickness of a blue individual hole transport layer serving as the individual hole transport layer disposed in the blue sub pixel is thinnest among the plurality of sub pixels.

19. The organic EL display device according to claim 16, wherein the plurality of sub pixels of the pixels comprise a red sub pixel, a red light emitting layer serving as the light emitting layer emitting red light being disposed in the red sub pixel.

20. An organic EL display device comprising pixels arranged on a display region in a matrix, the pixels comprising a plurality of sub pixels emitting light of different colors, the organic EL display device comprising:
a light emitting layer individually disposed in each sub pixel and emitting light of a different color for each sub pixel;
a positive electrode and a negative electrode arranged facing each other, the light emitting layer being disposed between the positive electrode and the negative electrode; and
a common hole transport layer common to each sub pixel, the common hole transport layer being disposed between the positive electrode and the light emitting layer,
wherein an individual hole transport layer is further individually disposed in each sub pixel, between the common hole transport layer and the light emitting layer for each sub pixel, and
an energy level value of a lowest unoccupied molecular orbital of the individual hole transport layer is smaller than an energy level value of a lowest unoccupied molecular orbital of the common hole transport layer for each sub pixel and greater than an energy level value of a lowest unoccupied molecular orbital of the light emitting layer in the sub pixel, and the plurality of sub pixels of the pixels comprise a blue sub pixel, a blue light emitting layer serving as the light emitting layer emitting blue light being disposed in the blue sub pixel, and
the individual hole transport layer disposed in a sub pixel other than the blue sub pixel is common across a plurality of the sub pixels other than the blue sub pixel among the plurality of sub pixels.

21. The organic EL display device according to claim 20, wherein a difference between an energy level value of a lowest unoccupied molecular orbital and an energy level value of a highest occupied molecular orbital is a HOMO-LUMO energy gap, and the HOMO-LUMO energy gap of a blue individual hole transport layer serving as the individual hole transport layer disposed in the blue sub pixel is largest among the plurality of sub pixels.
